(19) United States
(12) Patent Application Publication
(10) Pub. No.: US 2026/0231548 A1
(43) Pub. Date: Aug. 6, 2026

(54) IMAGE SENSOR AND METHOD OF MANUFACTURING THE SAME

(71) Applicant: Taiwan Semiconductor Manufacturing Company, Ltd., Hsinchu (TW)

(72) Inventors: Chih-Kuan Yu, Nantou County (TW); Feng-Chi Hung, Chu-Bei City (TW); Wen-I Hsu, Tainan City (TW); Jen-Cheng Liu, Hsin-Chu City (TW); Dun-Nian Yaung, Taipei City (TW)

(21) Appl. No.: 19/045,600

(22) Filed: Feb. 5, 2025

(51) Int. Cl. H10F 39/00; H10F 39/18

(52) U.S. Cl. CPC H10F 39/807; H10F 39/014; H10F 39/182; H10F 39/811

(57) ABSTRACT

Some embodiments relate to an integrated device, including: a substrate including a first surface and a second surface opposite the first surface; a plurality of photodetectors on the substrate and arranged in a grid pattern; a deep trench isolation (DTI) structure extending between the plurality of photodetectors, the DTI structure including: a first dielectric layer on the first surface and extending towards the second surface, a high work function (WF) layer including a metal or metal oxide and spaced from the substrate by the first dielectric layer, a second dielectric layer, wherein a first portion of the second dielectric layer is spaced from the first dielectric layer by the high WF layer, and an insulative fill extending between inner sidewalls of the second dielectric layer; wherein the high WF layer has a WF greater than 5 electron volts.

### BACKGROUND

Integrated circuits (ICs) with image sensors are used in a wide range of modern-day electronic devices such as, for example, cameras, cellphones, and the like. Image sensors use an array of photodetectors to detect an image and transfer signals derived from that image to an image processing circuit. Some image sensors use deep trench isolation (DTI) structures to reduce the crosstalk between photodetectors in the array.

### BRIEF DESCRIPTION OF THE DRAWINGS

Aspects of the present disclosure are best understood from the following detailed description when read with the accompanying figures. The figures are drawn to clearly illustrate relevant aspects of the embodiments. The figures may illustrate relationships between various structures and/or elements within the embodiments. It is noted that the figures are not necessarily drawn to scale. In some instances, the dimensions of the various features may be arbitrarily increased or reduced for clarity of discussion.

FIGS. 1A, 1B, and 1C illustrate cross-sectional views of some embodiments of a deep trench isolation (DTI) structure comprising a high work function (WF) layer.

FIGS. 2A and 2B illustrate a band diagram and a corresponding cross-sectional view of some embodiments of a DTI structure having a high WF layer separated from a substrate by a first dielectric layer.

FIGS. 3A, 3B, and 3C illustrate cross-sectional views of some embodiments of an image sensor with a DTI structure comprising a high WF layer where the DTI structure extends from a first surface to a second surface of the substrate.

FIGS. 4A, 4B, 4C, and 4D illustrate cross-sectional views and a top down view of an image sensor comprising a DTI structure that has first segments extending from the first surface to the second surface of the substrate and second segments extending partially into the substrate.

FIGS. 5A, 5B, 5C, and 5D illustrate cross-sectional views and a top down view of an image sensor comprising a DTI structure that extends partially into the substrate.

FIG. 6 illustrates a cross-sectional view of an image sensor with a DTI structure comprising a second dielectric layer lining inner sidewalls of the high WF layer.

FIGS. 7A, 7B, 7C, and 7D illustrate cross-sectional views of an image sensor with a DTI structure comprising a high WF layer that does not extend directly over the first surface of the substrate.

FIGS. 8-16 illustrate a series of cross-sectional views of some embodiments of a method of forming an image sensor with a DTI structure comprising a high WF layer.

FIG. 17 illustrates a flowchart of some embodiments of a method of forming an image sensor with a DTI structure comprising a high WF layer.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment. In some embodiments, the terms “approximately” and/or “about” can be interpreted as meaning +/−10% or +/−5%, while in other embodiments, the terms “approximately” and/or “about” can be interpreted as meaning within the normal fabrication tolerances of a given fab manufacturing flow.

An image sensor comprises a pixel array with a plurality of photodetectors and a plurality of pixel circuits coupled to the photodetectors. The plurality of photodetectors is organized in a plurality of rows and columns, forming a photodetector array. A plurality of microlenses are arranged over the photodetector array. A deep trench isolation (DTI) structure is used to separate and isolate the photodetectors from one another, reducing cross-talk and noise from nearby photodetectors.

In some embodiments, the process of forming the DTI structure damages the substrate surrounding the DTI structure. An etching process performed to etch trenches into the substrate damages inner sidewalls (e.g., regions of the substrate surrounding the trenches) of the trenches. Some of the damage takes the form of dangling bonds and dislocations in the substrate. The presence of dangling bonds and dislocations in the substrate results in additional eigenstates that electrons occupy that are different to those present in the undamaged regions substrate. The additional eigenstates (and therefore the damaged regions of the substrate) introduce noise into signals received from photodetectors exposed to the damage regions, resulting in reduced performance of the image sensor. An image sensor that reduces or eliminates the noise introduced by damaged regions of the substrate surrounding the DTI structure is desirable.

The present disclosure provides for a DTI structure comprising a high work function (WF) layer separated from the substrate by a first dielectric layer. The high WF layer is or comprises a metal oxide or a metal with a work function greater than 5 eV. The work function of the high WF layer is greater than the semiconductor WF of the surrounding substrate. The difference in WF between the high WF layer and the semiconductor material of the substrate induces a depletion region in the substrate in a region surrounding the DTI structure. The depletion region comprises a greater plurality of holes than electrons accumulating at the damaged region of the substrate. The plurality of holes increases the probability of electrons in the damaged region recombining with the plurality of holes, and lowers the probability of the electrons from the photodetector interacting with the dangling bonds and dislocations in the damaged region. The reduced interaction between the electrons and the dangling bonds and dislocations in the damaged region reduces the effect of the damaged region on the performance of the device by reducing noise and current leakage resulting from interactions between electrons and the additional eigenstates in the damaged region.

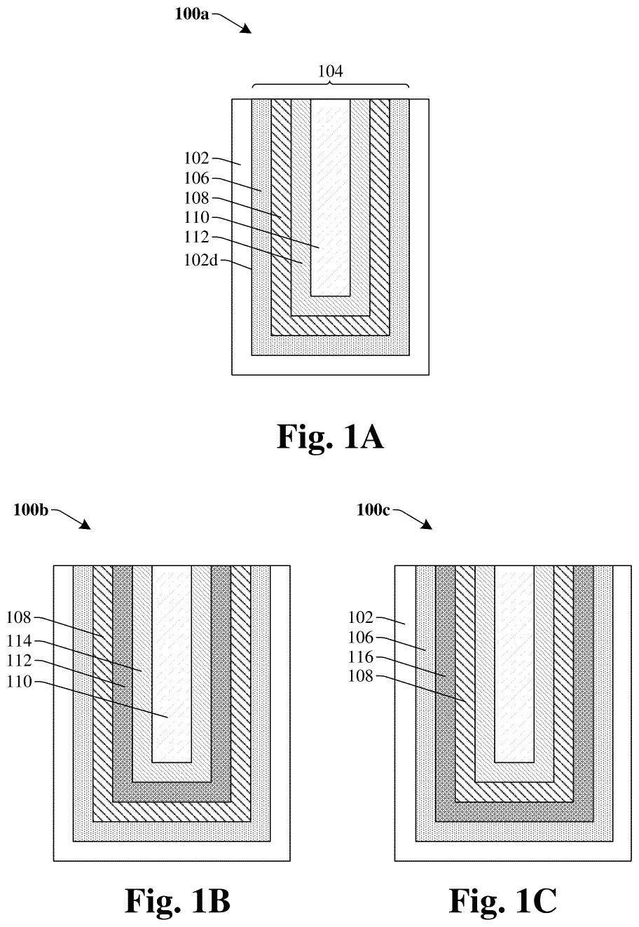

FIGS. 1A, 1B, and 1C illustrate cross-sectional views 100a, 100b, 100c of some embodiments of a deep trench isolation (DTI) structure comprising a high work function (WF) layer.

A DTI structure 104 extends into a substrate 102. The substrate 102 surrounds outer sidewalls of the DTI structure 104, and in some embodiments extends beneath the DTI structure 104. The DTI structure 104 comprises a first dielectric layer 106, a high WF layer 108, and an insulative fill 110. In some embodiments, the DTI structure 104 further comprises a second dielectric layer 112. The first dielectric layer 106 spaces the high WF layer 108 from the substrate 102. In some embodiments, the high WF layer 108 separates the second dielectric layer 112 from the first dielectric layer 106. The insulative fill 110 extends between inner sidewalls of the first dielectric layer 106, the high WF layer 108, and the second dielectric layer 112.

The high WF layer 108 is or comprises a material with a first work function greater than 5 eV. In some embodiments, the high WF layer 108 is or comprises a transparent metal oxide, such as indium tin oxide (ITO), zinc oxide (ZnO), or the like. In further embodiments, the transparent metal oxide of the high WF layer 108 is subjected to treatments (e.g., annealing processes performed in oxygen rich environments, oxygen plasma surface treatments, etc.) to increase the oxygen content of the material and the first work function of the material to equal to or greater than 5 eV. In other embodiments, the high WF layer 108 is or comprises a metal such as gold (Au), platinum (Pt), or the like.

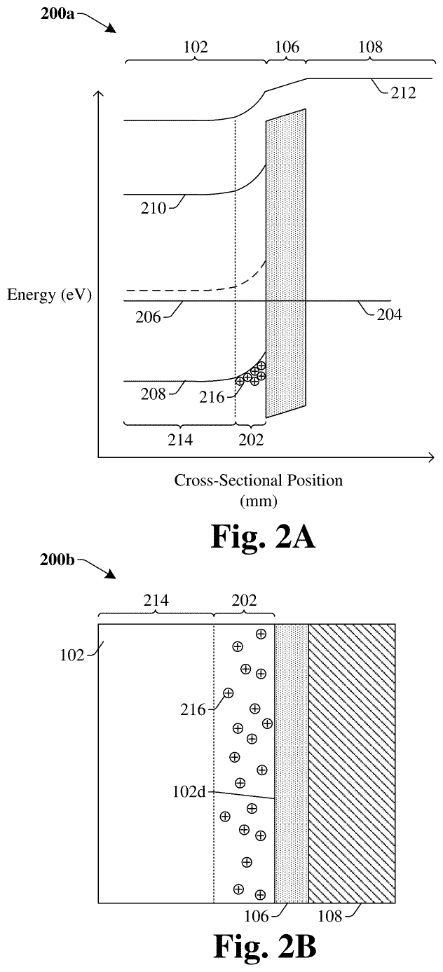

The first dielectric layer 106 isolates the high WF layer 108 from the substrate 102, substantially eliminating a transfer of charge carriers between the high WF layer 108 and the substrate 102. The substrate 102 has a second work function that is less than the first work function of the high WF layer 108. In some embodiments, the substrate 102 is or comprises a semiconductor material such as silicon or germanium and has a second work function between 4.5 and 4.9 eV. The difference in work function between the high WF layer 108 and the substrate 102 resulting in a depletion region (see 202 of FIGS. 2A, 2B) forming within the substrate 102. The depletion region (see 202 of FIGS. 2A, 2B) surrounds outer surfaces of the DTI structure 104, passivating the damaged inner sidewalls 102d of the substrate 102. The passivation reduces the amount of noise in the signals received from semiconductor devices that would otherwise be exposed to the damaged inner sidewalls 102d of the substrate 102. The passivation further reduces the amount of current leakage in photodetector arrays surrounded by the DTI structure 104.

As shown in the cross-sectional view 100b of FIG. 1B, in some embodiments, a third dielectric layer 114 comprising a different material than the second dielectric layer 112 extends between the high WF layer 108 and the insulative fill 110. As shown in the cross-sectional view 100c of FIG. 1C, in some embodiments, a fourth dielectric layer 116 comprising a different material than the first dielectric layer 106 separates the first dielectric layer 106 from the high WF layer 108. In some embodiments, the third and fourth dielectric layers 114, 116 provide additional insulation between the high WF layer 108 and the substrate 102 or the insulative fill 110.

FIGS. 2A and 2B illustrate a band diagram 200a and a corresponding cross-sectional view 200b of some embodiments of a DTI structure having a high WF layer separated from a substrate by a first dielectric layer. FIGS. 2A and 2B are described concurrently.

A first fermi level 204 of the high WF layer 108, and a second fermi level 206, a valence band 208, and a conduction band 210 of the substrate 102 are shown. The first fermi level 204, the second fermi level 206, the valence band 208, and the conduction band 210 are positioned according to the energy levels of the bands (shown on the vertical axis), and the horizontal position of the high WF layer 108, the first dielectric layer 106, and the substrate 102 shown in the cross-sectional view 200b (shown in the horizontal axis). When the system comprising the high WF layer 108, the first dielectric layer 106, and the substrate 102 are in equilibrium, the first fermi level 204 and the second fermi level have substantially the same energy level.

The first work function of the high WF layer 108 is the difference between the first fermi level 204 and the vacuum level 212 of the high WF layer 108. As the first work function is greater than the second work function, the vacuum level 212 of the substrate 102 is lower than the vacuum level 212 of the high WF layer 108. The vacuum level 212 is continuous across the band diagram 200a, so the vacuum level 212 rises throughout a portion of the substrate 102 and the first dielectric layer 106 to reach the vacuum level 212 at the high WF layer 108. The difference in energy between the vacuum level 212, the conduction band 210, and the valence band 208 of the substrate 102 remains substantially the same across the affected area, resulting in a corresponding rise in energy in the conduction band 210 and the valence band 208 near the interface between the substrate 102 and the first dielectric layer 106. The valence band 208 near the interface is closer to the second fermi level 206 than the valence band 208 at an outer region 214 of the substrate 102 further from the first dielectric layer 106. Further, the conduction band 210 near the interface is further from the second fermi level 206 than the conduction band 210 at an outer region 214 of the substrate 102 further from the first dielectric layer 106.

The difference in proximity of the conduction band 210 to the second fermi level 206 indicates a lower concentration of electrons (not shown) within the depletion region 202 than in the outer region 214, resulting in a greater concentration of holes 216 remaining in the depletion region 202. The combination of a greater concentration of holes 216 and reduced probability of electrons within the depletion region 202 passivates the interface between the substrate 102 and the first dielectric layer 106, reducing the interaction of electrons between the damaged inner sidewalls 102d of the substrate and devices in the outer region 214 of the substrate 102.

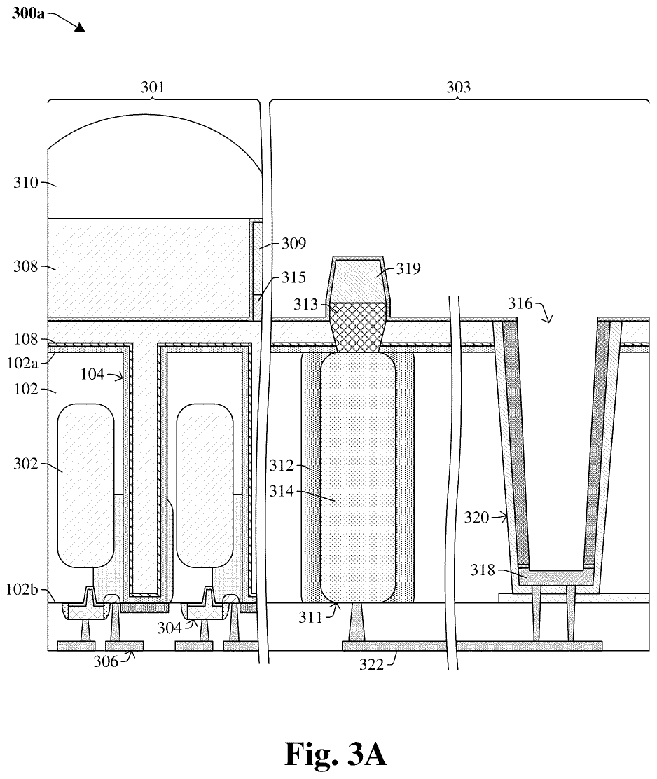

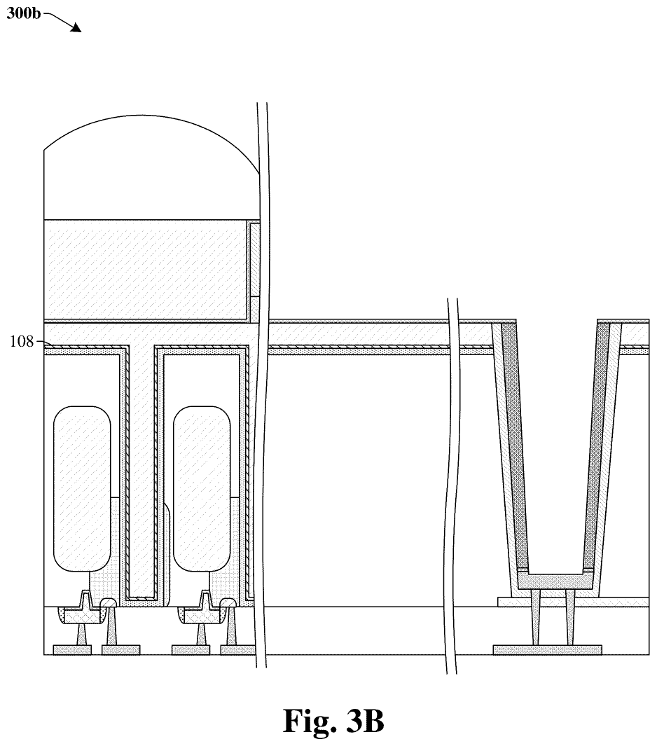

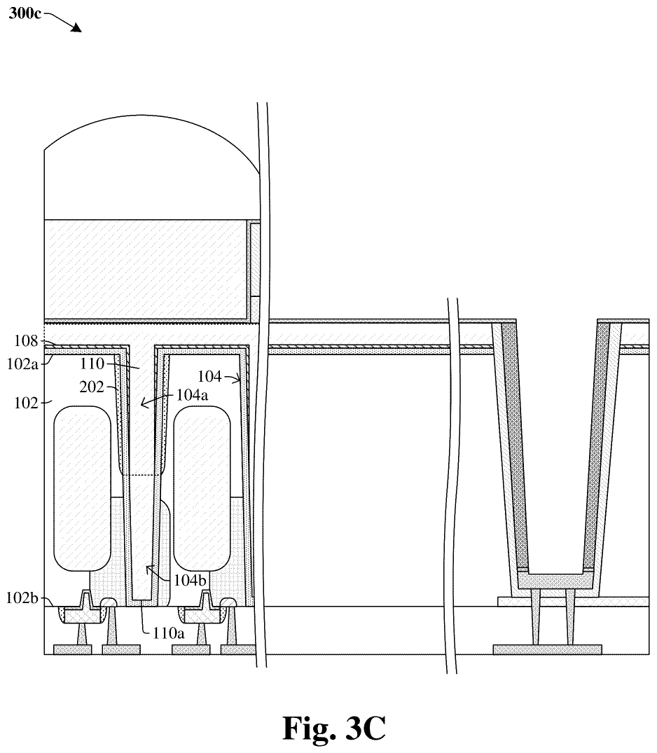

FIGS. 3A, 3B, and 3C illustrate cross-sectional views 300a, 300b, 300c of some embodiments of an image sensor with a DTI structure comprising a high WF layer where the DTI structure extends from a first surface to a second surface of the substrate.

As shown in the cross-sectional view 300a of FIG. 3A, in some embodiments, a plurality of photodetectors 302 are distributed in an array within the substrate 102. The plurality of photodetectors 302 are within a photodetector region 301. The plurality of photodetectors comprise n-type doped regions (e.g., regions bearing a concentration of n-type dopants greater than 10¹² atoms per cubic centimeter). Photodetectors of the plurality of photodetectors 302 are separated from each other by the DTI structure 104. In some embodiments, the DTI structure extends from a first surface 102a of the substrate 102 to a second surface 102b of the substrate 102, and physically isolates portions of the substrate 102 containing different photodetectors of the plurality of photodetectors 302.

A plurality of semiconductor devices 304 are on the second surface 102b of the substrate 102. In some embodiments, the plurality of semiconductor devices 304 are or comprise a transistor device (e.g., a planar FET, a FinFET, a gate-all-around (GAA) device, etc.). In some embodiments, the plurality of semiconductor devices 304 are or comprise transfer transistors of an image sensor circuit. In further embodiments, the image sensor comprises two bonded substrates, and the plurality of semiconductor devices 304 further comprise reset transistors, source follower transistors, row select transistors, or the like. In other embodiments, the image sensor comprises three bonded substrates, and the plurality of semiconductor devices 304 on the substrate 102 do not comprise reset transistors, source follower transistors, or row select transistors.

An interconnect structure 306 is on the second surface 102b of the substrate 102. The interconnect structure 306 is coupled to the plurality of semiconductor devices 304 and comprises a plurality of wire levels and via levels that couple the plurality of semiconductor devices 304 to other components (not shown) of the image sensor, such as the reset transistors, the source follower transistors, and the row select transistors in an image sensor using three bonded substrates, or an application specific integrated circuit (ASIC), such as an image processing circuit, in an image sensor using two bonded substrates.

A plurality of color filters 308 and microlenses 310 are on the first surface 102a of the substrate 102. In some embodiments, color filters of the plurality of color filters 308 extend over two or more photodetectors and are separated from one another by insulative barriers 309 overlying a metal grid structure 315. Color filters of the plurality of color filters 308 are centered on segments of the DTI structure 104 extending between two or more photodetectors. The insulative barriers 309 comprise a plurality of segments that directly overly segments of the DTI structure 104. In some embodiments, the microlenses 310 are centered on the DTI structure 104 extending between two or more photodetectors. In other embodiments, the microlenses 310 extend over but are laterally offset from the DTI structure 104 extending between two or more photodetectors.

In some embodiments, a conductive channel 311 extends between the first surface 102a and the second surface 102b of the substrate in a periphery region 303. The conductive channel 311 comprises a p-type doped channel 314 surrounded by a n-type doped well 312. A contact of the interconnect structure 306 couples the conductive channel 311 to the interconnect structure on the second surface 102b, and a conductive plug 313 couples the conductive channel 311 to the high WF layer 108 of the DTI structure on the first surface 102a. During operation, the high WF layer 108 is biased to induce higher concentrations of holes (see 216 of FIG. 2A) in the depletion region (see 202 of FIG. 2A), further increasing the passivation.

In some embodiments, a conductive pad structure 316 is formed in the substrate 102. The conductive pad structure 316 has an exposed wire 318 accessible from the first surface 102a of the substrate 102. A plurality of insulative layers 320 isolate the exposed wire 318 form the substrate 102. In some embodiments, the conductive pad structure 316 is configured to be used for testing of the integrated device before implementation. In other embodiments, the conductive pad structure 316 is coupled to the conductive channel 311 by a first wire 322 of the interconnect structure 306, and is configured to bias the high WF layer 108 when a voltage bias is applied to the exposed wire 318.

As shown in the cross-sectional view 300b of FIG. 3B, in some embodiments, the conductive channel (see 311 of FIG. 3A) is omitted, and the high WF layer 108 is not biased during operation. As shown in the cross-sectional view 300c of FIG. 3C, in some embodiments, the high WF layer 108 does not extend across lowermost surfaces 110a of the insulative fill 110. The lowermost surfaces 110a are the surfaces of the insulative fill 110 that are closest to and facing the second surface 102b of the substrate 102. The high WF layer 108 has lowermost points between the first surface 102a and the lowermost surfaces 110a and comprises a plurality of regions physically isolated by the insulative fill 110. In further embodiments, the depletion region 202 surrounds a first portion 104a of the DTI structure 104, and does not surround a second portion 104b of the DTI structure 104. In other embodiments, a reduced depletion region (not shown) (e.g., a depletion region with a lower concentration of holes than the depletion region 202) surrounds the second portion 104b of the DTI structure 104.

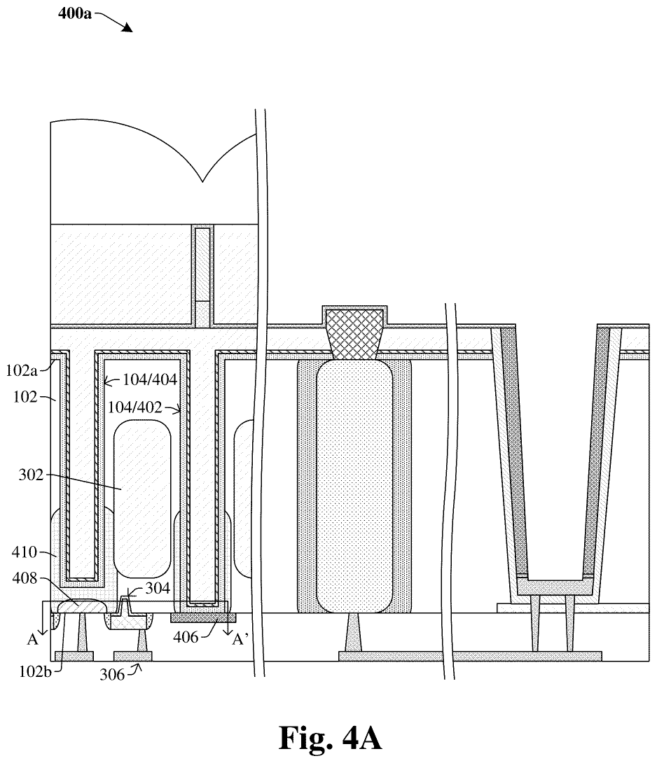

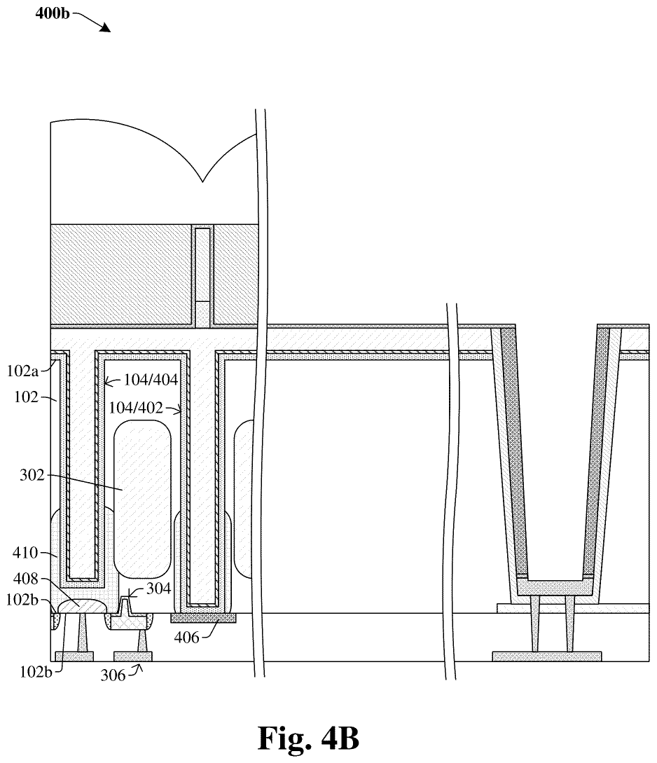

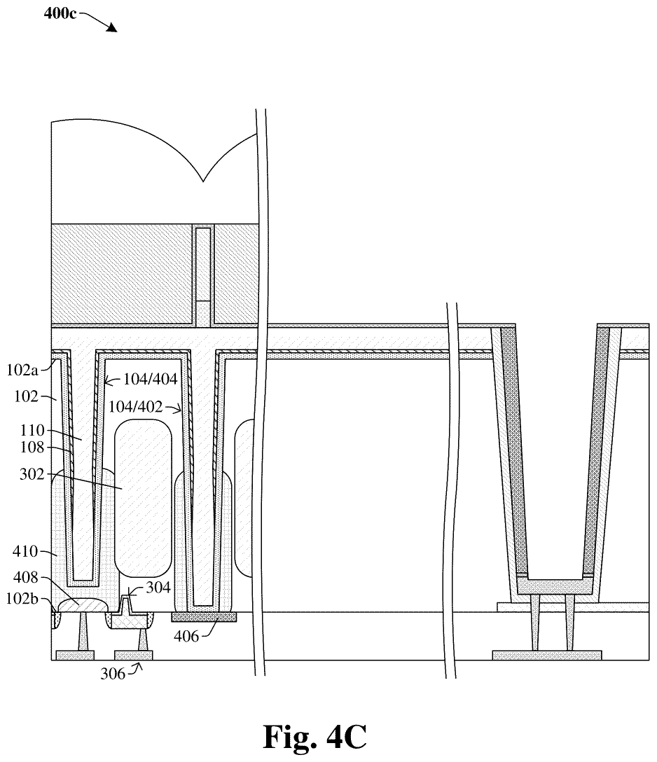

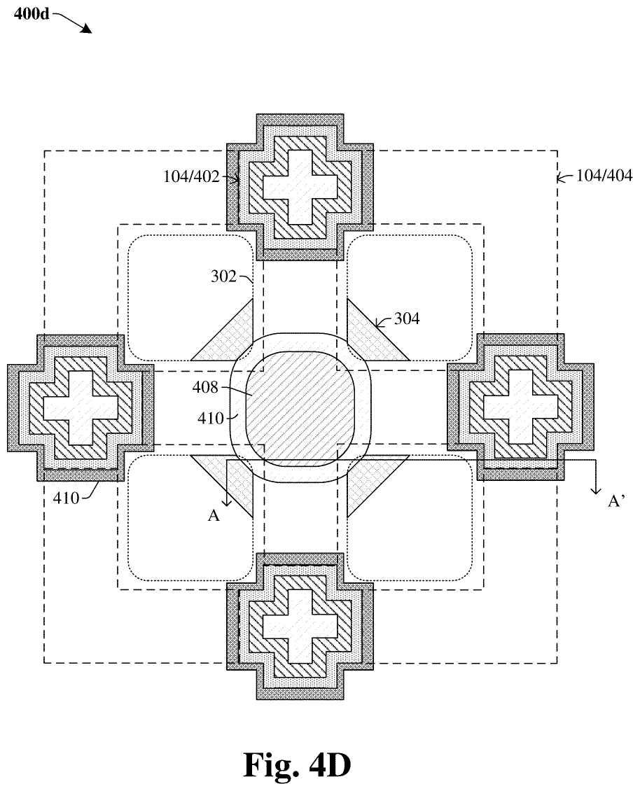

FIGS. 4A, 4B, 4C, and 4D illustrate cross-sectional views 400a, 400b, 400c and a top down view 400d of an image sensor comprising a DTI structure 104 that has first segments 402 extending from the first surface 102a to the second surface 102b of the substrate 102 and second segments 404 with bottommost surfaces between the first surface 102a and the second surface 102b of the substrate 102. FIGS. 4A and 4B are described concurrently. The cross-sectional view of FIG. 4A is taken along line A-A′ of FIG. 4D.

In some embodiments, etch stop layers 406 extend beneath the first segments 402. In some embodiments, floating diffusion regions 408 form a path for the charge from multiple photodetectors of the plurality of photodetectors 302 to enter the interconnect structure 306. The second segments 404 extend over the floating diffusion regions 408. In some embodiments, the first segments 402 are laterally displaced from the floating diffusion regions 408 and laterally surround the photodetectors. In other embodiments, the first segments 402 are positioned at intersections of the DTI structure 104 that are adjacent to the intersections directly overlying the floating diffusion regions 408 without surrounding the photodetectors 302 on sides opposite the intersections overlying the floating diffusion regions 408. In some embodiments, p-type doped regions 410 within the substrate 102 extend to the second surface 102b of the substrate 102 and surround outer sidewalls of the DTI structure 104. During operation, transfer transistors of the plurality of semiconductor devices 304 are biased to form conductive channels through the p-type doped regions 410 between the photodetectors and the floating diffusion regions 408. The p-type doped regions 410 are also referred to as positively doped regions.

In some embodiments, as shown in the cross-sectional view 400c of FIG. 4C, the high WF layer 108 extends into the p-type doped regions 410 without extending between the lowermost surfaces 110a of the insulative fill 110 and the second surface 102b of the substrate 102. That is, the high WF layer 108 extends into the p-type doped regions 410 and the insulative fill 110 extends further from the first surface 102a of the substrate 102 than the high WF layer 108. In other embodiments, a furthest point of the high WF layer 108 from the first surface 102a is spaced from the p-type doped region 410 in a direction perpendicular to the first surface 102a of the substrate 102.

As shown in the top down view 400d of FIG. 4D, in some embodiments, the first segments 402 extend in cross shapes from a top down perspective. In some embodiments, second segments 404 (shown in phantom) extend over the shared floating diffusion regions 408 and over intersections of the DTI structure 104 that are diagonal from intersections directly overlying the floating diffusion regions 408. In other embodiments, the first segments 402 extend over intersections of the DTI structure 104 that are diagonal from intersections directly overlying the floating diffusion regions 408, and extend between intersections that do not directly overly the floating diffusion regions 408. Transfer transistors of the semiconductor devices 304 surround the floating diffusion region 408. In some embodiments, the photodetectors 302 overly the transfer transistors and partially overly the p-type doped region 410.

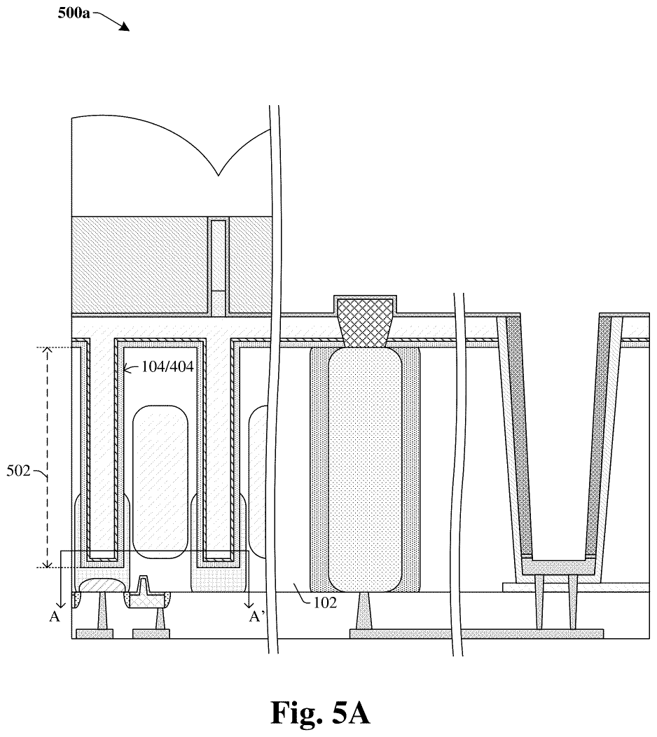

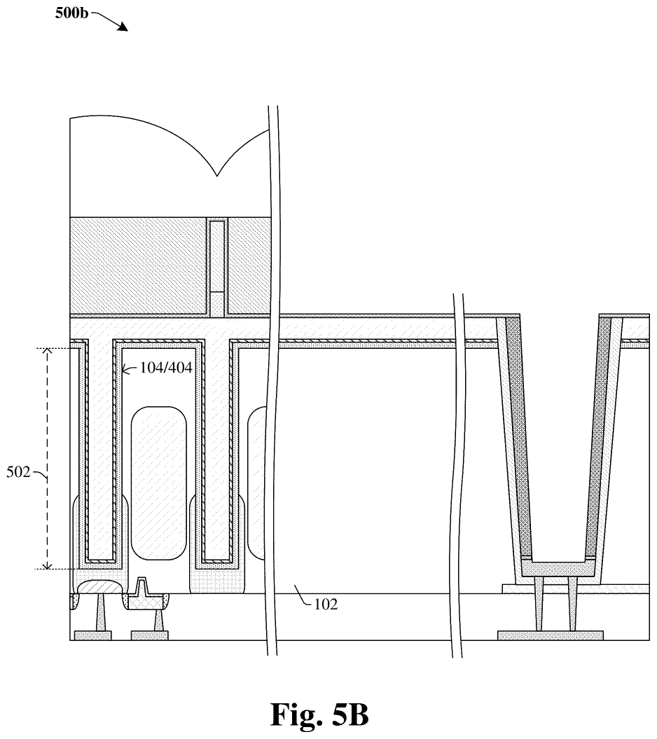

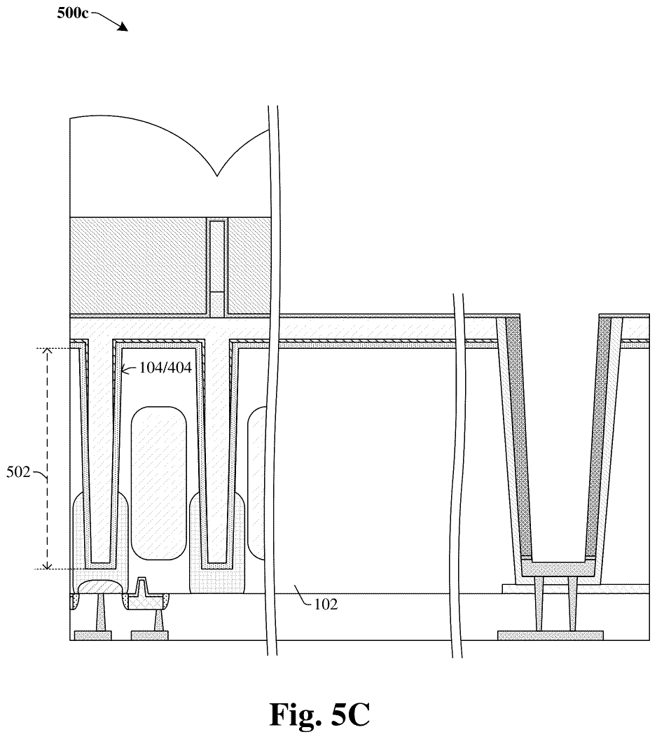

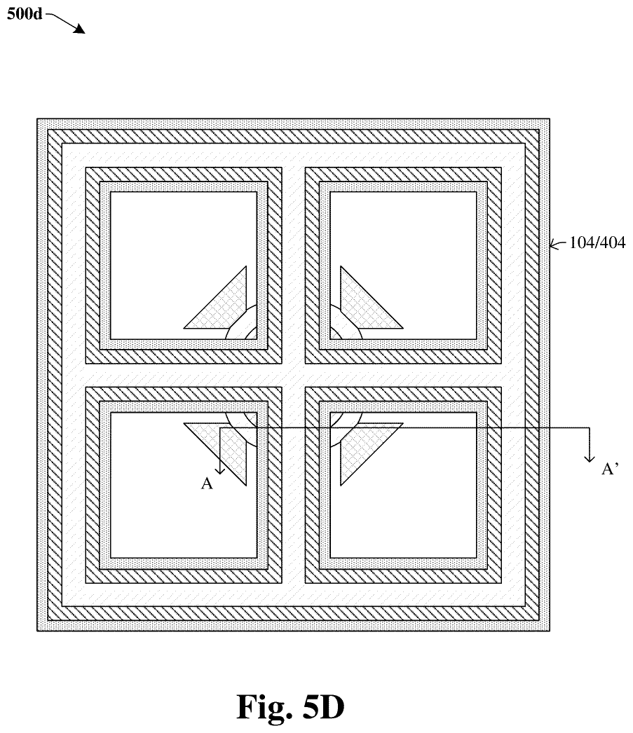

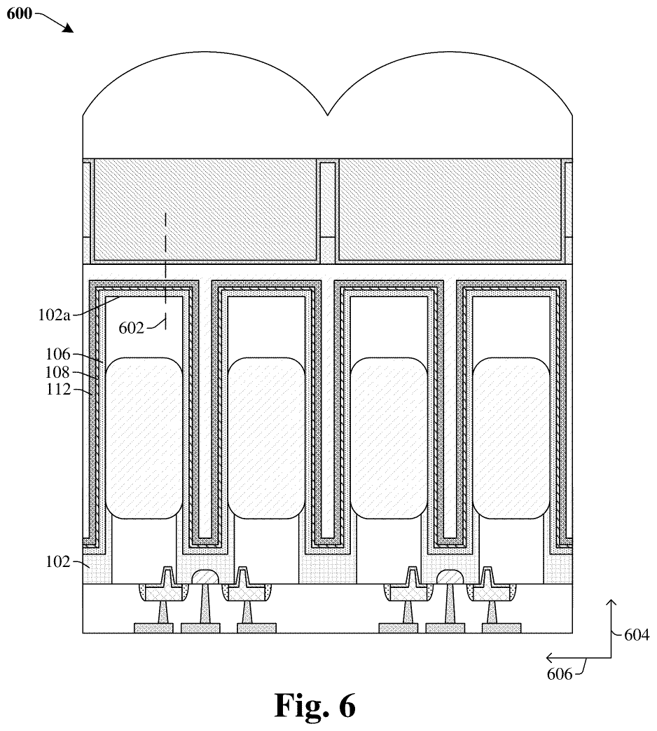

FIGS. 5A, 5B, 5C, and 5D illustrate cross-sectional views 500a, 500b, 500c and a top down view 500d of some embodiments of an image sensor comprising a DTI structure 104 that extends partially into the substrate 102. FIGS. 5A, 5B, 5C, and 5D are described concurrently. The cross-sectional view of FIG. 5A is taken along line A-A′ of FIG. 5D. In some embodiments, the DTI structure 104 is composed of second segments 404. In other words, the DTI structure 104 does not extend to the second surface 102b, and the depth 502 the DTI structure 104 extends to within the substrate 102 is approximately equal (e.g., within 5% of an average value) throughout the DTI structure 104.

FIG. 6 illustrates a cross-sectional view 600 of an image sensor with a DTI structure 104 comprising a second dielectric layer 112 lining inner sidewalls of the high WF layer 108. In some embodiments, the second dielectric layer 112, the high WF layer 108, and the first dielectric layer 106 have portions that directly overly the first surface 102a of the substrate 102, such that a first axis 602 extending in a first direction 604 perpendicular to the first surface 102a of the substrate 102 extends through a portion of the high WF layer 108, the first dielectric layer 106, and the second dielectric layer 112. That is, the high WF layer 108 extends past the first surface 102a in the first direction 604 and extends across the first surface in a second direction 606 perpendicular to the first direction 604.

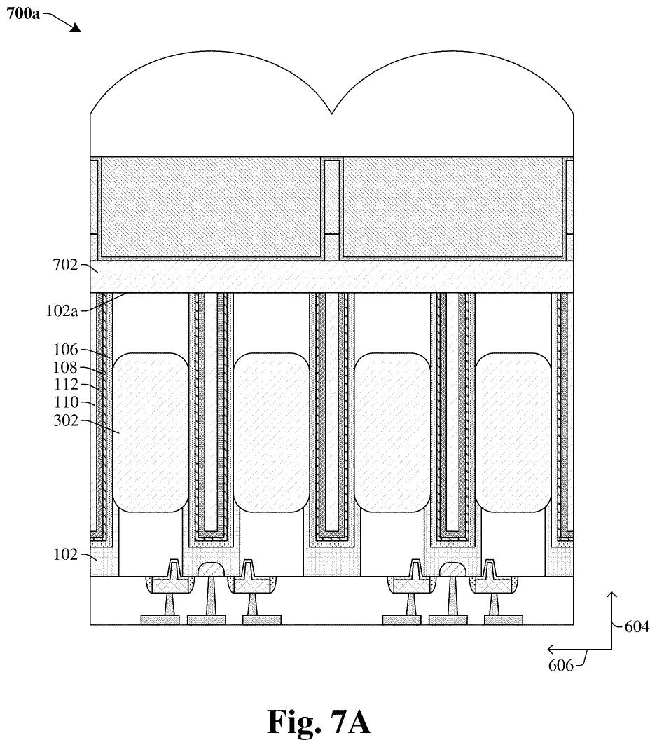

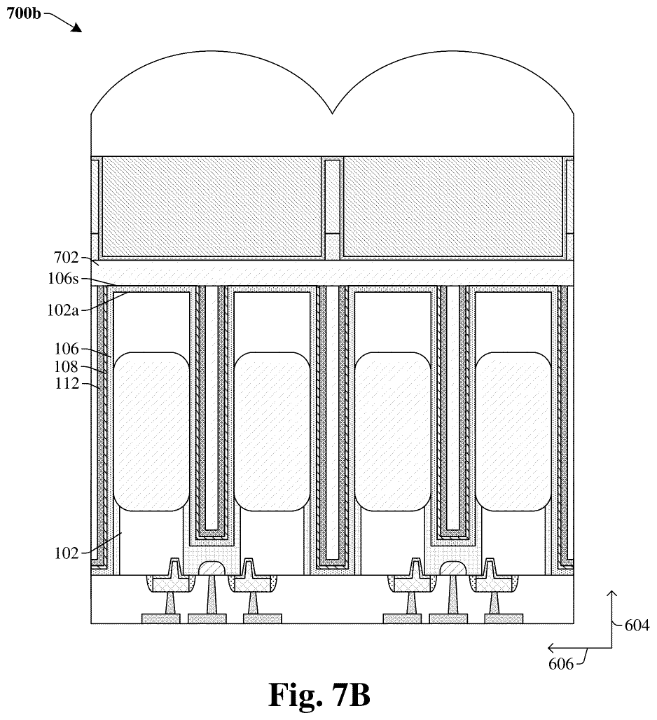

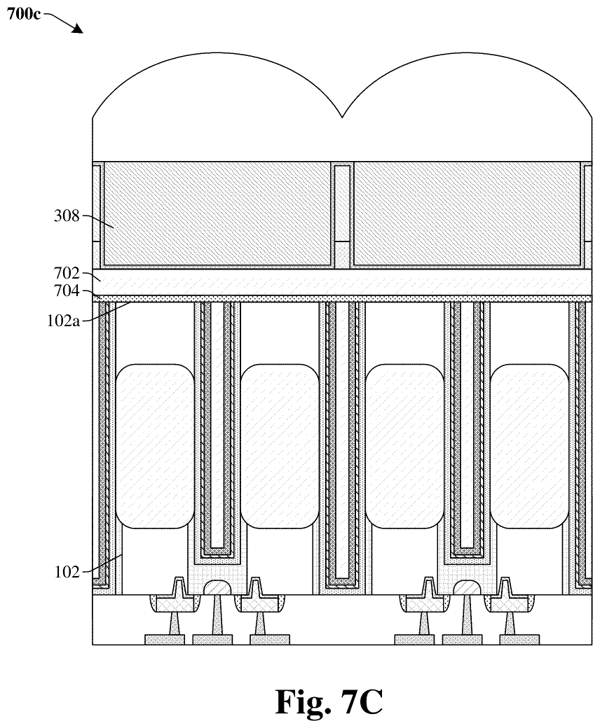

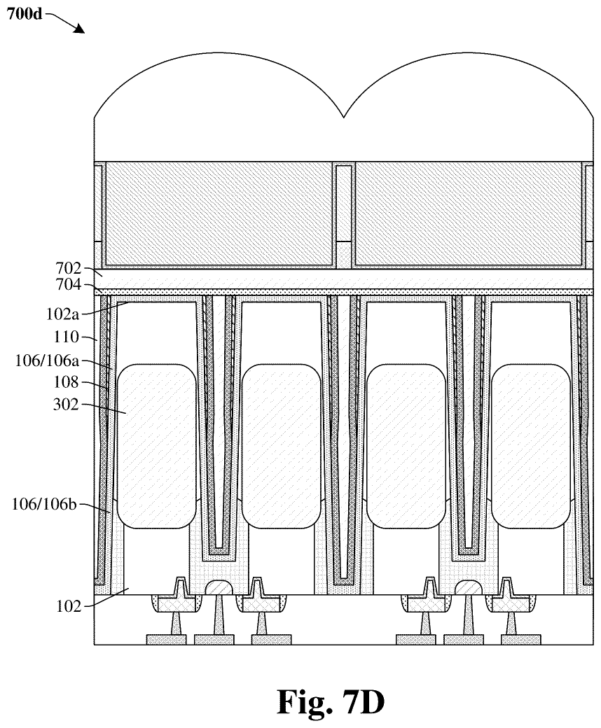

FIGS. 7A, 7B, 7C, and 7D illustrate cross-sectional views 700a, 700b, 700c, 700d of an image sensor with a DTI structure 104 comprising a high WF layer that does not extend directly over the first surface of the substrate. As shown in cross-sectional view 700a of FIG. 7A, in some embodiments, the second dielectric layer 112, the high WF layer 108, and the first dielectric layer 106 do not have portions that directly overly the first surface 102a of the substrate 102, and an additional insulative layer 702 extends over the first surface 102a of the substrate 102. That is, the high WF layer 108 is spaced from the first surface 102a of the substrate 102 in the second direction 606 parallel to the first surface 102a of the substrate 102 by the first dielectric layer 106. In further embodiments, the high WF layer 108 also does not extend beyond the lowermost surfaces 110a of the insulative fill 110 in the first direction 604, resulting in the high WF layer 108 being a plurality of electrically isolated rings surrounding the plurality of photodetectors 302.

As shown in cross-sectional view 700b of FIG. 7B, in other embodiments, the first dielectric layer 106 comprises portions that directly overly the first surface 102a of the substrate 102 and the second dielectric layer 112 and the high WF layer 108 do not comprise portions that directly overly the first surface 102a of the substrate 102. The additional insulative layer 702 extends over the first surface 102a of the substrate 102. In some embodiments, the first dielectric layer 106 has first outer surfaces 106s facing in a same direction (the first direction 604) as the first surface 102a of the substrate 102, and wherein the second dielectric layer 112 is spaced from the first surface 102a in the second direction 606 that is substantially parallel to the first surface 102a.

As shown in cross-sectional view 700c of FIG. 7C, in other embodiments, the additional insulative layer 702 and an additional dielectric layer extend over the first surface 102a of the substrate 102 and separate the color filters 308 form the substrate 102. As shown in cross-sectional view 700d of FIG. 7D, in other embodiments, the additional insulative layer 702 and an additional dielectric layer 704 are spaced from the substrate 102 by the first dielectric layer 106. In some embodiments, the high WF layer 108 covers inner sidewalls of a first portion 106a of the first dielectric layer 106 and does not cover a second portion 106b of the first dielectric layer 106. In further embodiments, as the high WF layer 108 does not contact other portions of the high WF layer 108 by extending over the first surface 102a of the substrate 102 or extend between the lowermost surfaces 110a of the insulative fill 110 and the second surface 102b, and the high WF layer 108 comprises a plurality of electrically isolated rings that surround the plurality of photodetectors 302.

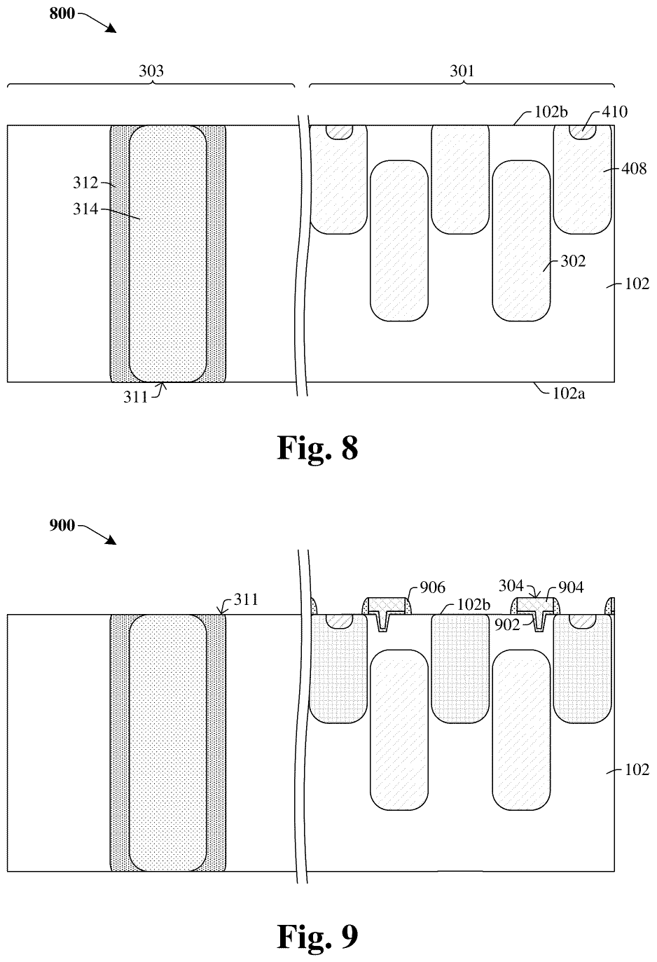

FIGS. 8-16 illustrate a series of cross-sectional views 800-1600 of some embodiments of a method of forming an image sensor with a DTI structure comprising a high WF layer. Although FIGS. 6-14 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

As shown in the cross-sectional view 800 of FIG. 8, the plurality of photodetectors 302, the floating diffusion regions 408, and the p-type doped regions 410 are formed within a photodetector region 301 of the substrate 102. In some embodiments, the plurality of photodetectors 302 are or comprise n-type regions of the substrate that are formed using an implantation process. The floating diffusion regions 408 are formed on the second surface 102b of the substrate 102. In some embodiments, the floating diffusion regions 408 are or comprise n-type regions (e.g., substrate regions with n-type doping) that are formed using an implantation process. The p-type doped regions 410 are or comprise substrate regions with p-type doping that are formed using an implantation process before the formation of the floating diffusion regions 408. The p-type doped regions 410 extend from the second surface 102b of the substrate 102 towards the first surface 102a of the substrate 102. In some embodiments, the p-type doped regions 410 extend in a grid pattern corresponding to the grid pattern and position of the DTI structure (see 104 of FIG. 1A) to be formed hereafter. In some embodiments, the substrate 102 is or comprises a semiconductor material such as silicon (Si), germanium (Ge), or the like. In some embodiments, the n-type dopants are or comprise one or more of phosphorus (P), arsenic (As), bismuth (Bi), lithium (Li), or the like. In some embodiments, the p-type dopants are or comprise one or more of boron (B), aluminum (Al), gallium (Ga), or the like.

In some embodiments, the conductive channel 311 is formed within the substrate 102. The conductive channel 311 is formed by implanting n-type dopants to form the n-type doped well 312, and implanting p-type dopants within the n-type doped well 312 to form the p-type doped channel 314. During operation, the n-type doped well 312 reduces the number of photoelectrons from the photodetectors that are attracted to the p-type doped channel 314. The conductive channel 311 is formed in a periphery region 303 of the substrate 102.

As shown in the cross-sectional view 900 of FIG. 9, the plurality of semiconductor devices 304 are formed on the second surface of the substrate 102. In some embodiments, a patterned etching step is performed to remove a portion of the substrate 102 such that the resulting semiconductor devices 304 extend into the substrate 102. After the etching step, a plurality of deposition (e.g., physical vapor deposition (PVD), atomic layer deposition (ALD), chemical vapor deposition (CVD), or the like) and patterned etching (e.g., dry etching or the like) steps are performed to form gate dielectrics 902 and gate electrodes 904.

In some embodiments, forming the gate electrodes 904 further comprises forming a sacrificial gate layer, patterning the sacrificial gate layer and gate dielectrics 902, forming an interlayer dielectric surrounding the patterned sacrificial gate layer, and replacing the sacrificial gate layer with the gate electrodes 904 by removing the sacrificial gate layer, forming a conformal conductive layer, and performing a planarization process (e.g., a chemical mechanical planarization (CMP) process) to remove portions of the conformal conductive layer over the interlayer dielectric. In other embodiments, the semiconductor devices 304 are formed by forming a conformal gate electrode layer over a conformal gate dielectric layer, and patterning both the conformal gate electrode layer and the conformal gate dielectric layer to form the gate dielectrics 902 and the gate electrodes 904. In some embodiments, insulative spacers 906 are formed around the gate electrodes 904 by forming a conformal insulative layer over the gate electrodes 904 and then performing a self-aligned etching process (e.g., and un-patterned etching process), resulting in vertical portions of the conformal insulative layer remaining as insulative spacers 906. In yet other embodiments, other processes are used to form the semiconductor devices 304, or multiple different processes are used to form different devices of the semiconductor devices 304.

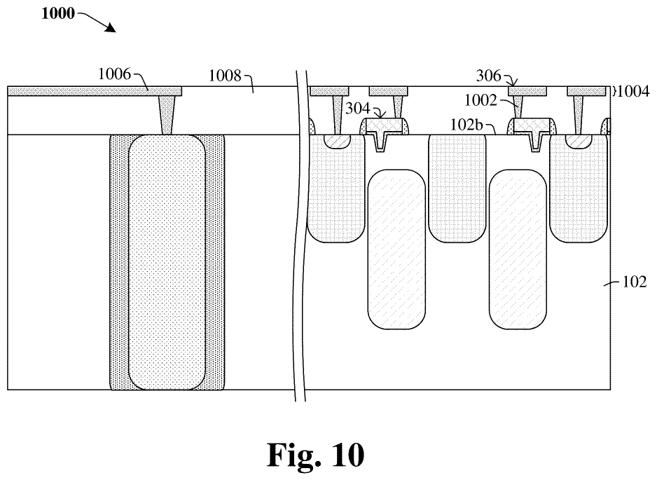

As shown in the cross-sectional view 1000 of FIG. 10, the interconnect structure 306 is formed over the semiconductor devices 304 and the second surface 102b of the substrate 102. The interconnect structure comprises contacts 1002 extending from the semiconductor devices 304 and the floating diffusion regions 408 to a first wire level 1004. In some embodiments, the contacts 1002 also couple the conductive channel 311 to a first wire 1006 of the first wire level 1004. In some embodiments, the interconnect structure 306 is formed by depositing an interlayer dielectric 1008 and using one or more of a damascene process, a dual damascene process, or the like. In some embodiments, a plurality of additional wire levels (not shown) and via levels (not shown) are formed over the first wire level by depositing additional interlayer dielectric layers and performing additional damascene processes, dual damascene processes, or the like. In some embodiments, the interconnect structure 306 is or comprises a conductive material such as gold (Au), copper (Cu), aluminum (Al), doped polysilicon, or another similar material.

In some embodiments, etch stop layers (see 406 of FIG. 4A) are formed on the second surface 102b of the substrate 102 before forming the interconnect structure 306 using a deposition process and a subsequent patterning process (e.g., forming and patterning a masking layer, then patterning the etch stop layers (see 406 of FIG. 4A) according to the masking layer). In some embodiments, the etch stop layers (see 406 of FIG. 4A) are or comprise an insulative material such as silicon nitride (Si₃N₄) or the like. In some embodiments, the interlayer dielectric is or comprises an insulative material such as silicon dioxide (SiO₂) or the like.

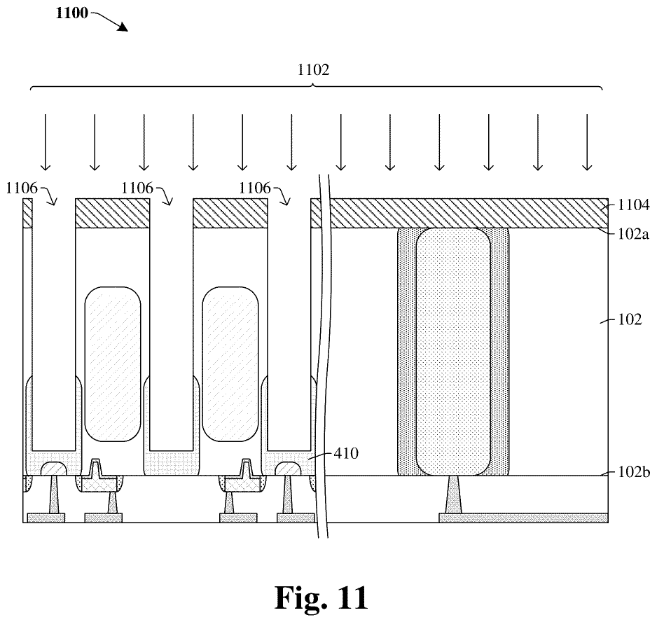

As shown in the cross-sectional view 1100 of FIG. 11, a first masking layer 1104 is formed over the first surface 102a of the substrate 102. In some embodiments, the first masking layer 1104 is formed using a deposition process, a spin on process, a dipping process, or the like. The first masking layer 1104 is then patterned. In some embodiments, the first masking layer 1104 is a photoresist and is patterned using photolithography. Openings in the first masking layer 1104 correspond to the position of the DTI structure (see 104 of FIGS. 1A, 5A) to be formed hereafter.

After the first masking layer 1104 is patterned, a first etching process 1102 is performed. In some embodiments, the first etching process 1102 is an anisotropic dry etching process. The first etching process results in a first plurality of openings 1106 corresponding to the position of the DTI structure (see 104 of FIGS. 1A, 5A). The first plurality of openings 1106 extend into the p-type doped regions 410. In some embodiments, the first plurality of openings 1106 extend to the second surface 102b of the substrate 102. In other embodiments, additional masks and etching process are performed such that openings corresponding to first segments (see 402 of FIG. 4A) of the DTI structure (see 104 of FIG. 4A) extend to the second surface 102b of the substrate 102 and second segments (see 404 of FIG. 4B) of the DTI structure (see 104 of FIG. 4A) are spaced from the second surface 102b by the substrate 102.

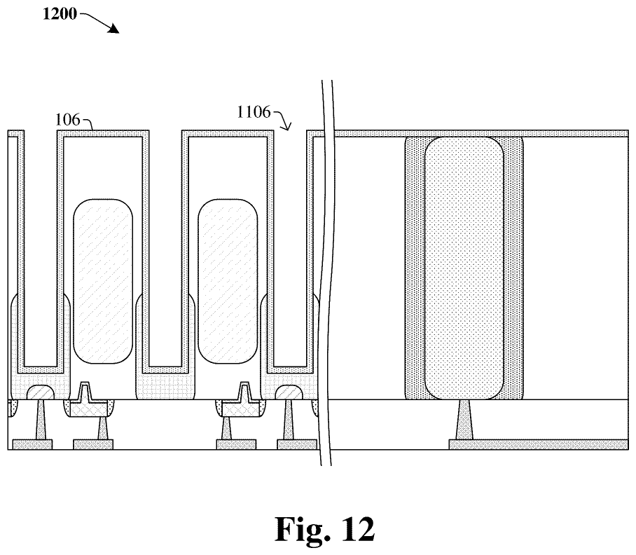

As shown in the cross-sectional view 1200 of FIG. 12, the first dielectric layer 106 is formed in the first plurality of openings 1106. In some embodiments, the first dielectric layer 106 is or comprises one or more of silicon dioxide (SiO₂), tantalum pentoxide (Ta₂O₅), titanium oxide (TiO₂), silicon nitride (Si₃N₄), or the like. In some embodiments, the first dielectric layer 106 is formed using one or more of PVD, ALD, CVD, or the like.

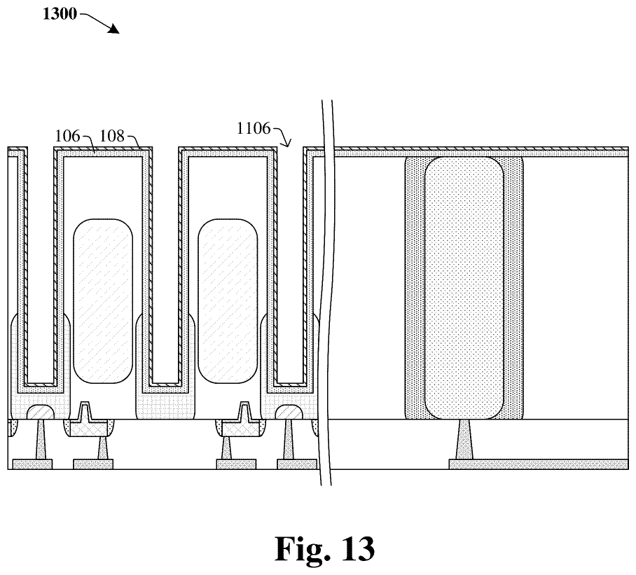

As shown in the cross-sectional view 1300 of FIG. 13, the high WF layer 108 is formed in the first plurality of openings 1106 over the first dielectric layer 106. The high WF layer 108 is separated from the substrate 102 by the first dielectric layer 106. In some embodiments, the high WF layer 108 covers inner sidewalls of a first portion (see 106a of FIG. 7D) of the first dielectric layer 106 without covering a second portion (see 106b of FIG. 7D) of the first dielectric layer (e.g., the high WF layer partially covers inner sidewalls of the first dielectric layer 106 as shown in FIGS. 3C, 4C, 5C, and 7D).

In some embodiments, the high WF layer 108 is formed using one or more of PVD, ALD, CVD, or the like. In some embodiments, the high WF layer 108 is or comprises a metal oxide. In further embodiments, additional treatments (e.g., annealing processes performed in oxygen rich environments, oxygen plasma surface treatments, etc.) are performed to increase the oxygen content and the first work function of the metal oxide material to equal to or greater than 5 eV. In other embodiments, the high WF layer 108 is or comprises a metal with a work function greater than 5 eV, such as gold (Au), platinum (Pt), or the like.

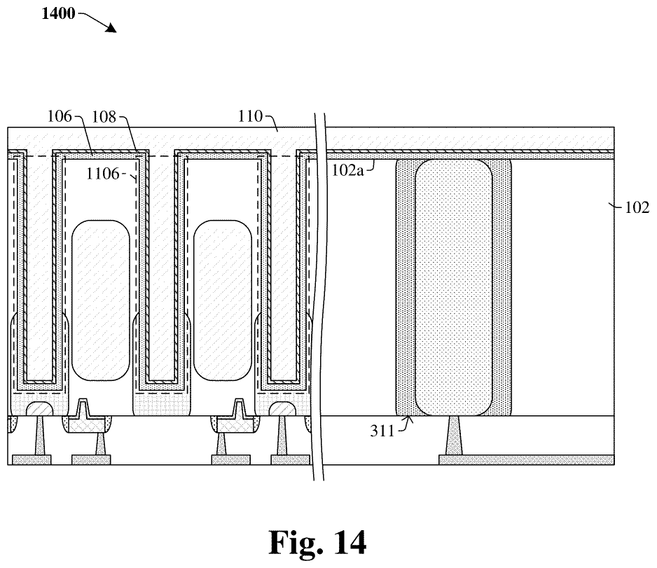

As shown in the cross-sectional view 1400 of FIG. 14, the insulative fill 110 is formed in the first plurality of openings 1106 (shown in phantom) over the first dielectric layer 106 and the high WF layer 108. The insulative fill 110 fills the first plurality of openings 1106 and extends over the first surface 102a of the substrate 102. In some embodiments, the insulative fill 110 is formed using one or more of PVD, ALD, CVD, or the like. In some embodiments, the insulative fill 110 is or comprises an insulative material, such as silicon dioxide (SiO₂), or the like. In some embodiments, the second dielectric layer (see 112 of FIGS. 1A, 6) is formed over the high WF layer 108 before the formation of the insulative fill 110.

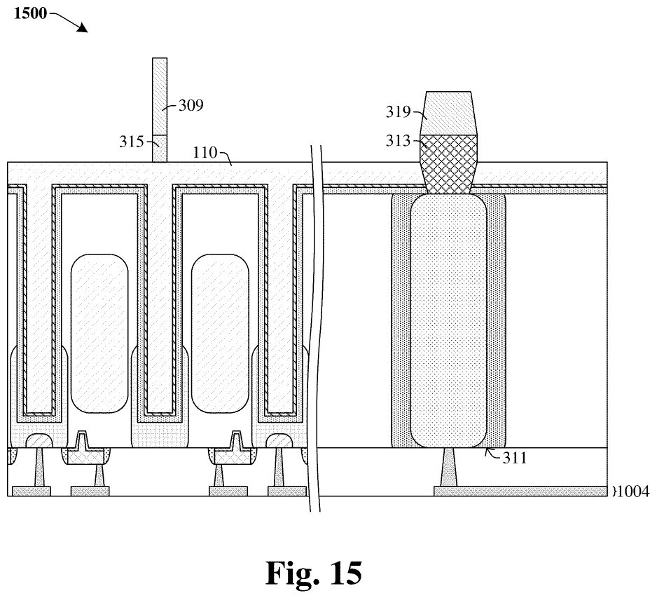

In some embodiments, the high WF layer 108 is or comprises a metal or an opaque metal oxide, and a removal process is performed to remove portions of the high WF layer 108 that directly overly the first surface 102a of the substrate 102. The removal process is or comprises an etching or planarization process. In further embodiments, the first dielectric layer 106 is also removed from the first surface 102a of the substrate 102. In other embodiments, the first dielectric layer 106 remains on the first surface 102a of the substrate 102 after the removal of the first dielectric layer 106 (e.g., see FIGS. 7A, 7B). In embodiments where portions of the high WF layer 108 are removed, an additional dielectric layer (see 704 of FIGS. 7C, 7D) and/or an additional insulative layer (see 702 of FIGS. 7C, 7D) are formed over the first surface 102a of the substrate 102. The method continues from embodiments where the high WF layer 108 is or comprises a transparent metal oxide and is not subject to the removal process described above. In embodiments where the high WF layer 108 is subject to the removal process, the formation of the conductive plug (see 313 of FIGS. 3A, 15) and the formation of the conductive channel 311 are omitted.

As shown in the cross-sectional view 1500 of FIG. 15, the conductive plug 313 and the metal grid structure 315 are formed over the first surface 102a of the substrate 102. In some embodiments, the conductive plug 313 and the metal grid structure 315 are formed concurrently by etching an opening through the insulative fill 110 (or the additional insulative layer (see 702 of FIGS. 7A-7D) to expose the conductive channel 311, forming a conformal metal layer, and patterning the conformal metal layer into the conductive plug 313 and the metal grid structure 315. In other embodiments, the conductive plug 313 and the metal grid structure 315 are formed using a damascene process within a sacrificial layer, and then removing the sacrificial layer. In other embodiments, the conductive plug 313 and the metal grid structure 315 are formed using nonconcurrent processes. In some embodiments, the insulative barriers 309 and the metal grid structure 315 are patterned using the same patterning process. In some embodiments, the insulative cap 319 on the conductive plug 313 and the conductive plug 313 are patterned using the same patterning process. In further embodiments, the insulative barriers 309 and the insulative cap 319 are patterned from the same insulative layer.

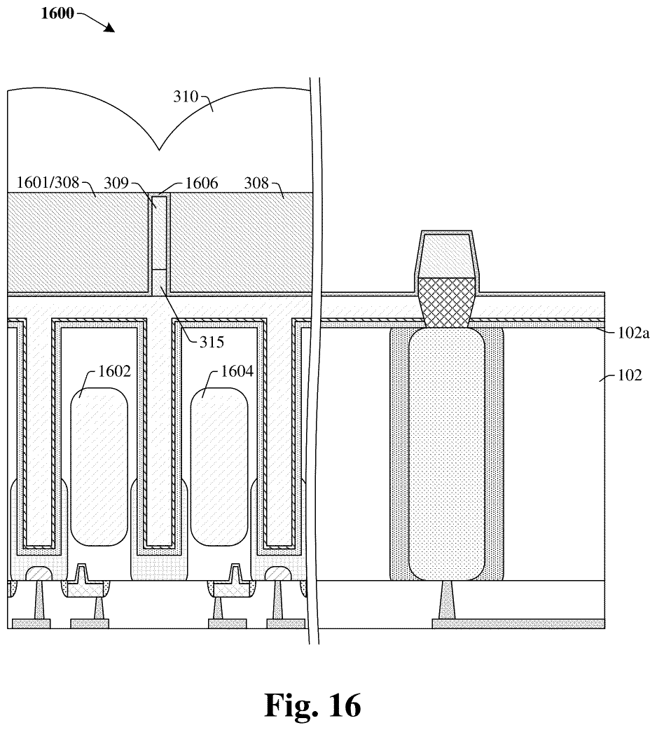

In some embodiments, the conductive pad structure (see 316 of FIG. 3A) is formed before forming the metal grid structure 315 or the conductive plug 313. The conductive pad structure (see 316 of FIG. 3A) is formed using a plurality of etching and deposition processes, resulting in the conductive pad structure (see 316 of FIG. 3A) having an exposed wire (see 318 of FIG. 3A) coupled to the first wire level 1004. The exposed wire (see 318 of FIG. 3A) is covered by an sacrificial fill through the formation of the microlenses (see 310 of FIGS. 3A, 16). The exposed wire (see 318 of FIG. 3A) is subsequently exposed by removing the sacrificial fill.

As shown in the cross-sectional view 1600 of FIG. 16, the plurality of color filters 308 and the plurality of microlenses 310 are formed on the first surface 102a of the substrate 102 in the photodetector region. In some embodiments, the plurality of color filters 308 are formed such that the colors filters independently overly two different photodetectors (e.g., a color filter 1601 extends directly over a first photodetector 1602 and a second photodetector (not shown), but not a third photodetector 1604 and a fourth photodetector (not shown). In other embodiments, the plurality of color filters 308 are formed such that the colors filters independently overly four different photodetectors. The plurality of color filters 308 are separated by the metal grid structure 315 and the insulative barriers 309. In some embodiments, an insulative conformal layer 1606 is formed before the plurality of color filters 308 and spaces the plurality of color filters 308 from the metal grid structure 315 and the insulative barriers 309.

In some embodiments, the plurality of microlenses 310 are positioned such that the microlenses are individually centered on the color filters of the plurality of color filters 308. In other embodiments, the plurality of microlenses 310 are offset from the centers of the color filters based on their position on the photodetector array. That is, microlenses 310 near a central portion of the photodetector array may be centered on the color filters 308 directly beneath them, while microlenses 310 near the edges of the photodetector array may be offset from the center of the color filters 308 to more effectively capture the incident light that is approaching at an oblique angle.

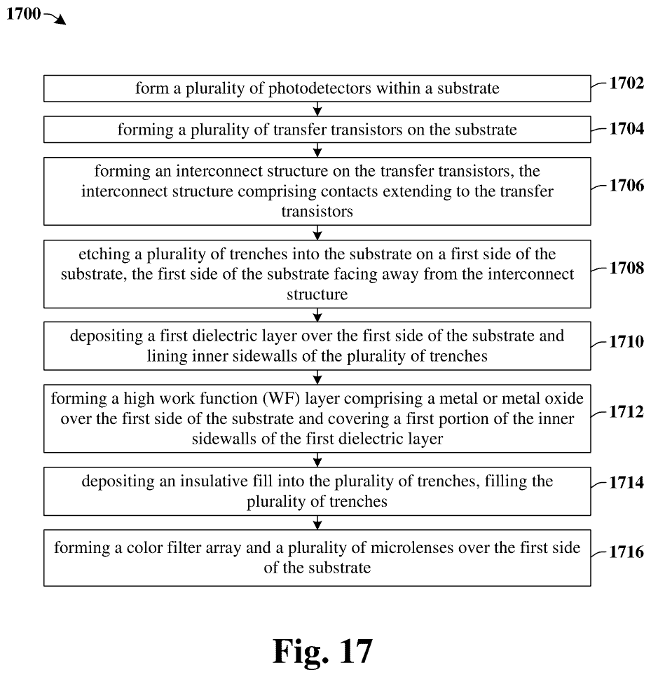

FIG. 17 illustrates a flowchart 1700 of some embodiments of a method of forming an image sensor with a DTI structure comprising a high WF layer. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At 1702, a plurality of photodetectors are formed within a substrate. An example of a drawing illustrating this step can be found, for example, in FIG. 8.

At 1704, a plurality of transfer transistors are formed on the substrate. An example of a drawing illustrating this step can be found, for example, in FIG. 9.

At 1706, an interconnect structure is formed on the transfer transistors, the interconnect structure comprising contacts extending to the transfer transistors. An example of a drawing illustrating this step can be found, for example, in FIG. 10.

At 1708, a plurality of trenches are etched into the substrate on a first surface of the substrate, the first surface of the substrate facing away from the interconnect structure. An example of a drawing illustrating this step can be found, for example, in FIG. 11.

At 1710, a first dielectric layer is formed over the first surface of the substrate and lining inner sidewalls of the plurality of trenches. An example of a drawing illustrating this step can be found, for example, in FIG. 12.

At 1712, a high work function (WF) layer comprising a metal or metal oxide over the first surface of the substrate and covering a first portion of the inner sidewalls of the first dielectric layer. An example of a drawing illustrating this step can be found, for example, in FIG. 13.

At 1714, an insulative fill is deposited into the plurality of trenches, filling the plurality of trenches. An example of a drawing illustrating this step can be found, for example, in FIG. 14.

At 1716, a color filter array and a plurality of microlenses over the first surface of the substrate. An example of a drawing illustrating this step can be found, for example, in FIG. 16.

Some embodiments relate to an integrated device, including: a substrate including a first surface and a second surface opposite the first surface; a plurality of photodetectors on the substrate and arranged in a grid pattern; and a deep trench isolation (DTI) structure extending between the plurality of photodetectors, the DTI structure including: a first dielectric layer on the first surface and extending towards the second surface, a high work function (WF) layer including a metal or metal oxide and spaced from the substrate by the first dielectric layer, a second dielectric layer, wherein a first portion of the second dielectric layer is spaced from the first dielectric layer by the high WF layer, and an insulative fill extending between inner sidewalls of the second dielectric layer; wherein the high WF layer has a WF greater than 5 electron volts.

Other embodiments relate to an integrated device, including: a substrate comprising a first surface and a second surface; a first dielectric layer extending into the substrate from the first surface towards the second surface and comprising inner sidewalls; a high work function (WF) layer lining inner sidewalls of the first dielectric layer and comprising inner sidewalls; a second dielectric layer lining the inner sidewalls of the high WF layer; and an insulative fill extending between inner sidewalls of the second dielectric layer; wherein the high WF layer has a work function greater than 5 electron volts.

Yet other embodiments relate to a method of forming an integrated device, including: forming a plurality of photodetectors within a substrate; forming a plurality of transfer transistors on the substrate; forming an interconnect structure on the transfer transistors, the interconnect structure comprising contacts extending to the transfer transistors; etching a plurality of trenches into the substrate on a first surface of the substrate, the first surface of the substrate facing away from the interconnect structure; depositing a first dielectric layer over the first surface of the substrate and lining inner sidewalls of the plurality of trenches; forming a high work function (WF) layer comprising a metal or metal oxide over the first surface of the substrate and covering a first portion of the inner sidewalls of the first dielectric layer; and depositing an insulative fill into the plurality of trenches, filling the plurality of trenches.

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated device, comprising:
a substrate comprising a first surface and a second surface opposite the first surface;
a plurality of photodetectors within the substrate and arranged in a grid pattern; and
a deep trench isolation (DTI) structure extending between the plurality of photodetectors, the DTI structure comprising:
a first dielectric layer on the first surface and extending towards the second surface,
a high work function (WF) layer comprising a metal or metal oxide and spaced from the substrate by the first dielectric layer,
a second dielectric layer, wherein a first portion of the second dielectric layer is spaced from the first dielectric layer by the high WF layer, and
an insulative fill extending between inner sidewalls of the second dielectric layer;
wherein the high WF layer has a WF greater than 5 electron volts.

2. The integrated device of claim 1, wherein the high WF layer comprises a transparent metal oxide and wherein a first axis extending perpendicular to the first surface of the substrate extends through a portion of the high WF layer.

3. The integrated device of claim 2, wherein the transparent metal oxide of the high WF layer extends from a first side of the high WF layer contacting the first dielectric layer to a second side of the high WF layer contacting the second dielectric layer.

4. The integrated device of claim 1, wherein the high WF layer comprises a metal and is spaced from the first surface of the substrate in a direction parallel to the first surface of the substrate by the first dielectric layer.

5. The integrated device of claim 4, wherein the metal of the high WF layer extends from a first side of the high WF layer contacting the first dielectric layer to a second side of the high WF layer contacting the second dielectric layer.

6. The integrated device of claim 1, wherein a second portion of the second dielectric layer contacts the first dielectric layer.

7. The integrated device of claim 1, wherein the first portion of the second dielectric layer extends beneath the insulative fill.

8. An integrated device, comprising:
a substrate comprising a first surface and a second surface;
a first dielectric layer on the first surface, extending towards the second surface and comprising inner sidewalls;
a high work function (WF) layer lining inner sidewalls of the first dielectric layer and comprising inner sidewalls;
a second dielectric layer lining the inner sidewalls of the high WF layer; and
an insulative fill extending between inner sidewalls of the second dielectric layer;
wherein the high WF layer has a work function greater than 5 electron volts.

9. The integrated device of claim 8, wherein the first dielectric layer further comprises a first portion that is between the first surface and the second surface of the substrate and a second portion that is spaced from the second surface by the first surface of the substrate.

10. The integrated device of claim 9, wherein the first dielectric layer has first outer surfaces facing in a same direction as the first surface of the substrate, and wherein the second dielectric layer is spaced from the first outer surface in a direction substantially parallel to the first outer surface.

11. The integrated device of claim 8, further comprising:
a conductive channel within the substrate extending from the first surface to the second surface;
a conductive plug on the first surface and coupling the conductive channel to the high WF layer; and
an interconnect structure on the second surface and coupled to the conductive channel.

12. The integrated device of claim 8, further comprising a doped region of the substrate comprising p-type dopants, wherein a first portion of the first dielectric layer extends between the first surface and the doped region, wherein a second portion of the first dielectric layer extends into the doped region.

13. The integrated device of claim 12, wherein the high WF layer extends a first depth into the substrate measured from the first surface, wherein the second dielectric layer extends a second depth into the substrate measured from the first surface, and wherein the first depth is greater than the second depth.

14. The integrated device of claim 12, wherein the high WF layer extends a first depth into the substrate measured from the first surface, wherein the second dielectric layer extends a second depth into the substrate measured from the first surface, wherein the first depth is less than the second depth, and wherein the high WF layer extends into the doped region of the substrate.

15. The integrated device of claim 12, wherein the high WF layer extends a first depth into the substrate measured from the first surface, wherein the second dielectric layer extends a second depth into the substrate measured from the first surface, wherein the first depth is less than the second depth, and wherein a furthest point of the high WF layer from the first surface is spaced from the doped region in a first direction perpendicular to the first surface of the substrate.

16. A method of forming an integrated device, comprising:
forming a plurality of photodetectors within a substrate;
forming a plurality of transfer transistors on the substrate;
forming an interconnect structure on the transfer transistors, the interconnect structure comprising contacts extending to the transfer transistors;
etching a plurality of trenches into the substrate on a first surface of the substrate, the first surface of the substrate facing away from the interconnect structure;
depositing a first dielectric layer over the first surface of the substrate and lining inner sidewalls of the plurality of trenches;
forming a high work function (WF) layer comprising a metal or metal oxide over the first surface of the substrate and covering a first portion of the inner sidewalls of the first dielectric layer; and
depositing an insulative fill into the plurality of trenches, filling the plurality of trenches.

17. The method of claim 16, further comprising:
removing a portion of the high WF layer extending past the first surface of the substrate after depositing the insulative fill.

18. The method of claim 17, wherein a second portion of the inner sidewalls of the first dielectric layer are exposed after forming the high WF layer and before depositing the insulative fill into the plurality of trenches; and
wherein the removal of the portion of the high WF layer extending past the first surface of the substrate after depositing the insulative fill results in the high WF layer comprising a plurality of electrically isolated rings surrounding the plurality of photodetectors.

19. The method of claim 16, further comprising forming positively doped regions in the substrate before forming the transfer transistors, wherein the plurality of trenches are etched into the positively doped regions.

20. The method of claim 19, wherein a second portion of the inner sidewalls of the first dielectric layer are exposed after forming the high WF layer and before depositing the insulative fill into the plurality of trenches; and
wherein the high WF layer extends to the positively doped regions in the substrate in a first direction perpendicular to the first surface of the substrate.
